(19) United States
(12) Patent Application Publication
(10) Pub. No.: US 2025/0357263 A1
(43) Pub. Date: Nov. 20, 2025

(54) COMPOSITE THERMAL HOTSPOT MANAGEMENT IN DIE PACKAGING

(71) Applicant: Diamond Foundry Inc., South San Francisco, CA (US)

(72) Inventors: Jeroen Van Duren, Fremont, CA (US); Martin Roscheisen, San Francisco, CA (US); Tong Zhao, Fremont, CA (US); Liubo Hong, San Jose, CA (US)

(21) Appl. No.: 19/044,723

(22) Filed: Feb. 4, 2025

Related U.S. Application Data
(63) Continuation of application No. PCT/US24/30242, filed on May 20, 2024.

(51) Int. Cl. H01L 23/427; H01L 23/00; H01L 23/538; H01L 25/18; H10B 80/00; H10D 80/30

(52) U.S. Cl. CPC H01L 23/427; H01L 23/538; H01L 24/29; H01L 24/32; H01L 25/18; H10B 80/00; H10D 80/30; H01L 2224/29109; H01L 2224/29111; H01L 2224/29139; H01L 2224/29144; H01L 2224/29147; H01L 2224/29155; H01L 2224/2957; H01L 2224/29639; H01L 2224/29644; H01L 2224/29647; H01L 2224/29687; H01L 2224/29688; H01L 2224/32225; H01L 2924/1431; H01L 2924/1436; H01L 2924/1437

(57) ABSTRACT

A device package includes a diamond heat spreader and a filler material bonded to a first side of the diamond heat spreader. A first integrated circuit (IC) device coupled to a second side of the diamond heat spreader opposite the filler material. A second IC device wherein a first side of the filler material opposite of a side bonded to the heat spreader shares a horizontal plane with a top side of the second IC device.

### CLAIM OF PRIORITY

This application is a continuation of International Patent Application Number PCT/US2024/030242 filed May 20, 2024, the entire contents of which are incorporated herein by reference.

### FIELD OF THE DISCLOSURE

Aspects of the present disclosure relate to heat mitigation in integrated circuit devices, specifically aspects of the present disclosure relate to diamond heat spreaders coupled to integrated circuit devices.

### BACKGROUND OF THE DISCLOSURE

Heat mitigation is an important aspect of modern computing architecture. Integrated circuit (IC) devices such as microprocessors, Random Access Memory (RAM), microcontrollers, transistors, etc. may generate a lot of heat during operation, which, if left unmitigated, may build up and damage them. One common solution is to place a heatsink or heat spreader over the IC device.

A surface match between the heatsink or heat spreader and the IC device is desirable to have efficient flow of heat to the heat spreader or heatsink. A gap may cause a hotspot as the void between the two interfaces may collect more heat in the IC device. These gaps may inhibit the flow of heat between the two interfaces and eventually lead to failure of the IC device as it cannot dump enough heat to the heat spreader or heatsink. Gaps between the heat spreader and the IC device may be filled with thermal interface material (TIM) sometimes referred to as thermal paste, thermal grease, thermal pad, thermal gel, phase change material, thermally conductive adhesive or epoxy, thermal tape, carbon nanotube (CNT) TIM, composite TIM, filled polymer TIM, gap fillers, graphite sheets, solder, or metal TIM (e.g., indium). The TIM presents its own set of problems as the thermal conductance of the TIM may be lower than that of the heat spreader or heatsink, which may slow down or limit thermal transfer to the heat sink or heat spreader. A TIM often has a significantly lower thermal conductivity than the heat spreader or the heatsink and adds considerable thermal resistance. Additionally, a typical TIM usually has inconsistent properties due to outgassing, thickness variations, or performance dependence on applied pressure (force). Thus, it is advantageous to create a match between the surface of the heatsink or heat spreader in contact with the surface of the IC device.

A simple way IC manufacturers ensure a good match between interfaces is by lapping, grinding, or polishing the surface of the IC device that will contact the heatsink or heat spreader. Likewise, the heat spreader or heat sink may be lapped, grinded, or polished at the intended interface to the IC device. The low surface roughness and increased flatness of each of the interfaces may create a good connection for thermal conductance.

Modern device packages based on IC devices, sometimes called chip packages, are being designed and developed to run with more operations per second and with smaller footprints. This results in chip packages that generate more heat. One such new chip package is the so-called 2.5D chip package based on an interposer. An example of a Prior Art design for a 2.5D chip package is shown in FIG. 1. As shown, the 2.5D chip package 100 includes a processor 101 IC device and dynamic random-access memory (DRAM) 102 IC devices stacked on top of each other (high bandwidth memory stack, DRAM cubes, or HBM) on top of a logic die 108 connected by RAM interconnect layers 103. The term processor or logic die as used herein may include microcontrollers, application specific integrated circuits (ASICs), field programmable gate arrays (FPGAs), microprocessors, and the like. Microprocessors may include central processing units (CPUs), accelerator processing units (APUs), graphics processing units (GPUs), neural processing units (NPUs), etc.

The RAM devices 102 may be communicatively coupled to the processor 101 by one or more interconnects part of the interposer 104. Conductive vertical interconnects 105 (e.g. balls, bumps, pillars, or vias) may connect the processor 101 and the RAM devices 102 to the (horizontal) interconnect(s) part of the interposer 104 on top of the laminate or ceramic substrate 109. Similarly large conductive vertical interconnects 110 may connect and/or bond the interposer 104 to the laminate or ceramic substrate 109. At the bottom of the substrate large vertical interconnects (e.g. BGA balls) connect the substrate to a PCB board (both these large vertical interconnects and PCB board are not shown in FIG. 1). As shown here, in prior implementations the processor 101 consists of a small active region 106 where processing takes place and a large region of inactive silicon. During production, the large region of inactive silicon may be lapped, grinded, or polished down to share a horizontal plane 107 with the top of the RAM 102 stack. This creates a smooth, flat surface to interface with heatsinks or heat spreaders. An issue with silicon is that it is not as thermally conductive as other materials. Thus, the large inactive region of silicon poses an issue for efficient heat transfer in newer hotter running devices.

It is within this context that aspects of the present disclosure arise.

### BRIEF DESCRIPTION OF THE DRAWINGS

The teachings of the present disclosure can be readily understood by considering the following detailed description in conjunction with the accompanying drawings, in which:

FIG. 1 depicts a side cross-section diagram of a prior art 2.5D device package according to an aspect of the present disclosure.

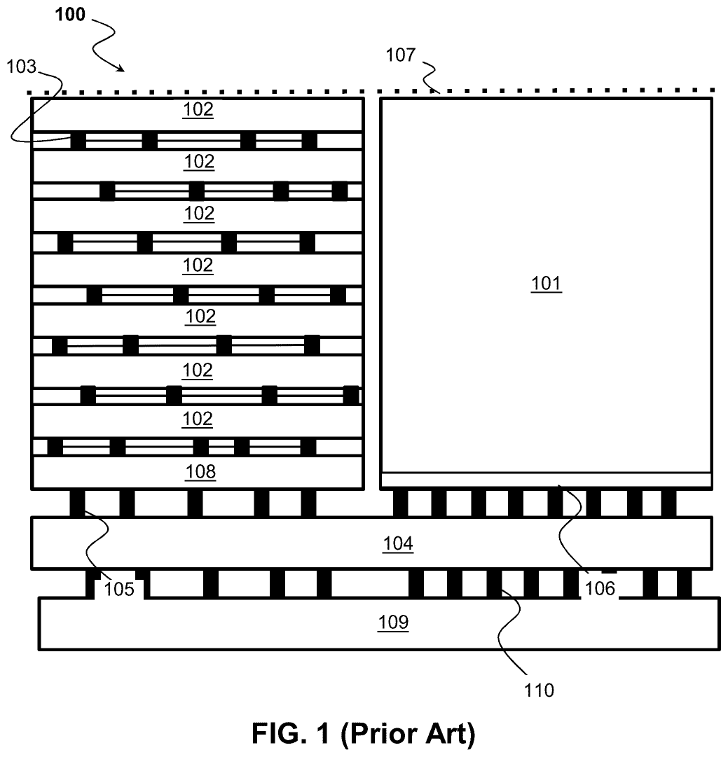

FIG. 2A depicts a side cross-section view of a device package having a processor coupled to a diamond heat spreader bonded to filler material height matched to one or more second IC device(s) according to an aspect of the present disclosure.

FIG. 2B depicts a side cross-section view of a device package having the diamond heat spreader with a rough surface at the interface with the processor that is smoothened by a smoothening material and a smooth surface at the interface with the filler material according to an aspect of the present disclosure.

FIG. 2C depicts a side cross-section view of a device package having the diamond heat spreader with a rough surface that is smoothened by a smoothing material at the interface with the filler material according to an aspect of the present disclosure.

FIG. 2D depicts a side cross-section view of a device package having the diamond heat spreader with a first side having a rough surface that is smoothened by a first smoothening material and a second side having a rough surface that is smoothened by a second smoothing material according to an aspect of the present disclosure.

FIG. 2E depicts a side cross-section view of a device package having the diamond heat spreader with a rough surface at the interface with the processor that is smoothened by a smoothening material and a smooth surface at the interface with the filler material according to an aspect of the present disclosure.

FIG. 3 depicts a side cross-section view of a device package having a diamond lid heat spreader according to an aspect of the present disclosure.

FIG. 4 depicts a top-down schematic view of a device package having a diamond lid heat spreader according to an aspect of the present disclosure.

FIG. 5 is a top-down schematic view of the device package having two processors coupled to a single diamond heat spreader bonded to filler material height matched to one or more second IC device(s) according to an aspect of the present disclosure.

FIG. 6 depicts a top-down schematic view of the device package having each processor coupled to a single diamond heat spreader bonded to filler material height matched to one or more second IC device(s) according to an aspect of the present disclosure.

FIG. 7A depicts a cross-section view of a device package having a 3-D stacked processing system IC device with a diamond heat spreader with height matching to a memory stack according to an aspect of the present disclosure.

FIG. 7B depicts a cross-section view of a device package having a 3-D stacked processing system IC device with multiple stacked processing units and a diamond heat spreader with height matching to a memory stack according to an aspect of the present disclosure.

FIG. 7C depicts a cross-section view of a device package having 3-dimensionally (3D) stacked IC devices and a diamond heat spreader with height matching according to an aspect of the present disclosure.

FIG. 7D depicts a cross-section view of a device package having 3D stacked IC devices and two diamond heat spreaders with height matching according to an aspect of the present disclosure.

### DESCRIPTION OF THE SPECIFIC EMBODIMENTS

Although the following detailed description contains many specific details for the purposes of illustration, anyone of ordinary skill in the art will appreciate that many variations and alterations to the following details are within the scope of the invention. Accordingly, examples of embodiments of the invention described below are set forth without any loss of generality to, and without imposing limitations upon, the claimed invention.

In the following Detailed Description, reference is made to the accompanying drawings, which form a part hereof, and in which are shown by way of illustration specific embodiments in which the invention may be practiced. In this regard, directional terminology, such as “top,” “bottom,” “front,” “back,” “leading,” “trailing,” etc., is used with reference to the orientation of the figure(s) being described. Because components of embodiments of the present disclosure can be positioned in a number of different orientations, the directional terminology is used for purposes of illustration and is in no way limiting. It is to be understood that other embodiments may be utilized, and structural or logical changes may be made without departing from the scope of the present invention. The following detailed description, therefore, is not to be taken in a limiting sense, and the scope of the present invention is defined by the appended claims.

Single crystal diamond is an extremely effective thermal conductor with a thermal conductivity of about 2200 Watts per meter Kelvin (W·m⁻¹·K⁻¹). Thus, single crystal diamond may be an effective material for spreading heat away from IC devices and the hotspots in these IC devices. As such, integration of single crystal diamond into devices and/or device packages has been proposed. Ideally the diamond heat spreader could replace the large inactive silicon region of the processor, e.g. in a 2.5D package. However, it is very costly to make thick single crystal diamond plates or wafers. Thus, it is currently not cost effective to create a heat spreader completely out of diamond that is as thick as a silicon wafer, e.g. 775 micrometers thick. Additionally, diamond is an extremely hard material and, as such, polishing the diamond to a smoothness compatible with advanced bonding techniques like plasma-assisted bonding (PAB, or fusion bonding), and surface activated bonding (SAB or COMBOND) is very costly.

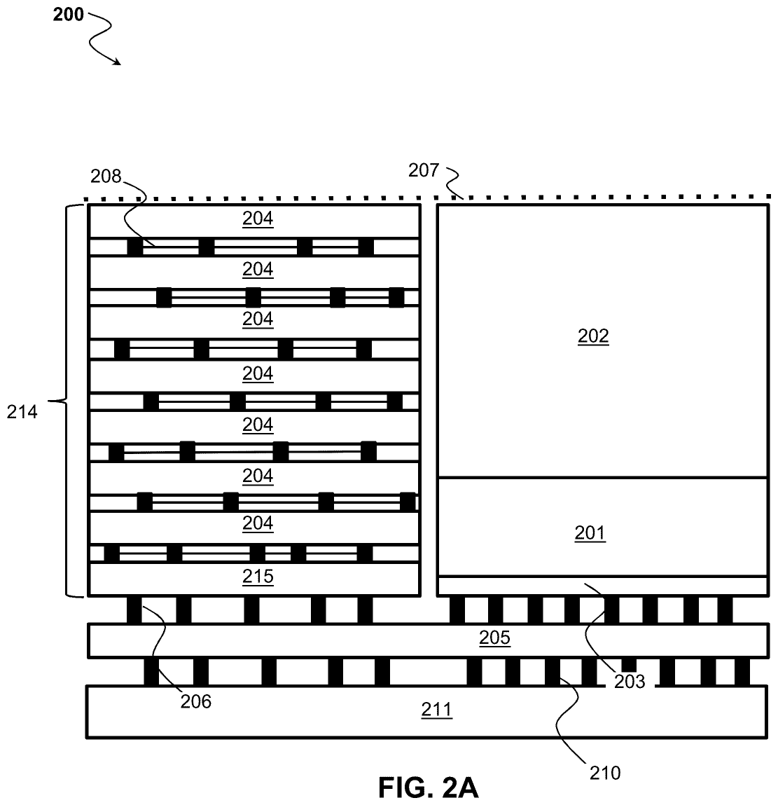

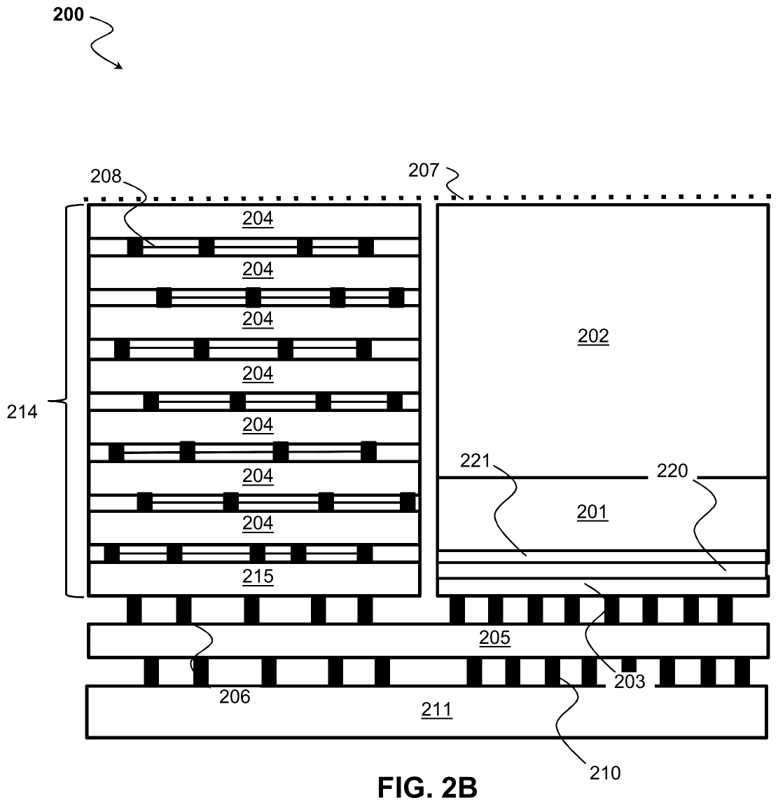

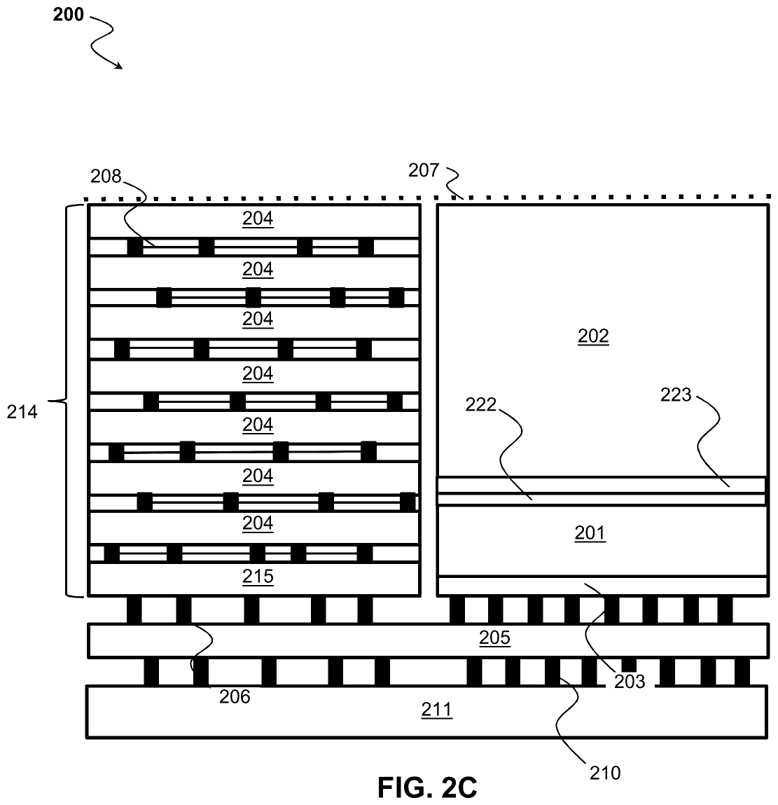

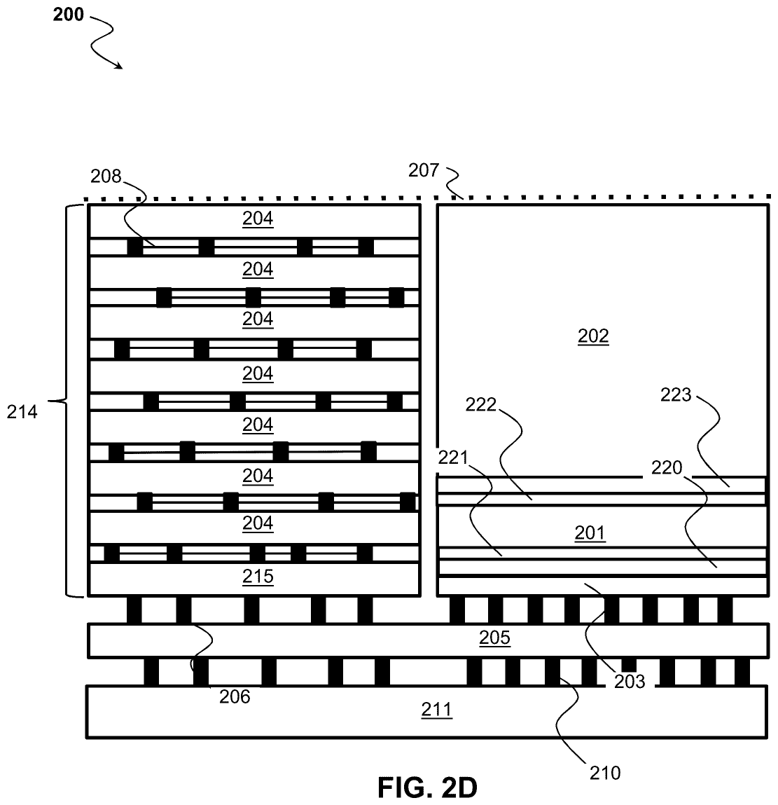

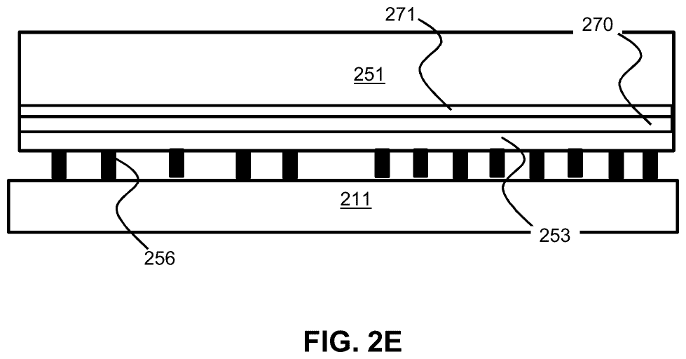

Thus, a combination of heat spreader with other filler materials bonded to the single crystal diamond heat spreader is proposed according to aspects of the present disclosure. FIG. 2A depicts a side cross-sectional view of a device package 200 having a processor 203 coupled to a single crystal diamond heat spreader 201 bonded to filler material 202 that is height matched to a second IC device according to an aspect of the present disclosure. In this implementation the processor 203 IC device is thinned to less than 150 micrometers, preferably less than 30 micrometers, even more preferred less than 10 micrometers, even more preferred less than 500 nanometers, even more preferred less than 50 nanometers, getting closer to the active region and removing most of the (electrically) inactive (passive) silicon substrate. The processor 203 is communicatively connected to an interposer 205 through conductive vertical interconnects 206. The interposer 205 may be bonded and/or communicatively connected to a laminate or ceramic substrate 211 by large vertical interconnect 210 for example and without limitation, large solder balls. The interposer may have horizontal or vertical interconnects, or both. The laminate or ceramic substrate may have horizontal or vertical interconnects, or both. Vertical interconnects may be through the whole thickness, or only part of the thickness, or both. The horizontal interconnects may be buried, or on top, or both. The interposer may be made out of any suitable material known in the art, for example, silicon, or an organic material. The laminate substrate may include for example and without limitation resin, or epoxy. The ceramic substrate may be made out of any suitable material for example and without limitation, glass. The interconnects may include a conductive material, for example and without limitation, copper.

In the implementation depicted in FIG. 2A, the second IC device includes a memory stack 214 having multiple random-access memory (RAM) devices 204 stacked on top of one another and connected via interconnects 208. It is noted that aspects of the present disclosure are not limited to implementations involving stacks of memory devices as the second IC device. As shown the top of the thinned processor 203, that is the side of the processor opposite the side connected to the interposer through the vertical conductive interconnects, is at a significantly lower height from the common plane created by the interposer 205 than the memory stack 214.

The diamond heat spreader 201 is bonded or attached to filler material 202. The diamond heat spreader may be made from nanocrystalline diamond, microcrystalline diamond, polycrystalline diamond or more preferably single crystal diamond. The diamond heat spreader may be a stack of two or more layers of different crystalline forms of diamond. The diamond heat spreader may consist of natural carbon-12 (¹²C) isotope concentrations (e.g. 98.9% ¹²C), or the diamond heat spreader may be enriched in ¹²C above its natural concentration (e.g. enriched to 99.7% ¹²C). The ¹²C concentration may be homogeneous in the diamond heat spreader, or vary in the diamond heat spreader. The ¹²C concentration in the diamond heat spreader may vary from one side to the other, e.g. a higher ¹²C concentration closer to the processor 203. Furthermore, the diamond heat spreader may have a thermal conductivity at room temperature above 400 W/m-K, more preferably above 1,000 W/m-K, even more preferably above 2,000 W/m-K, or even above 3,000 W/m-K. The diamond heat spreader may have a homogeneous thermal conductivity, or the thermal conductivity may vary in the diamond heat spreader. The diamond heat spreader may have a higher thermal conductivity closer to the processor 203. The diamond heat spreader may be 50 micrometers thick, more preferably 100 micrometers thick, even more preferably thicker than 200 micrometers. The diamond heat spreader may be of the same size (lateral dimensions) as the processor 203, or the diamond heat spreader may be of a different size (e.g. smaller, or larger).

Additionally, the diamond heat spreader 201 may be made from multiple diamond plates or a single diamond plate. A side of a diamond heat spreader 201 is attached to a side of the processor 203 IC device opposite the side connected to interposer 205 through the vertical interconnects 206. Likewise, the diamond heat spreader 201 is attached to the processor 203 on a side opposite the side bonded to the filler material 202. The lateral dimensions of the diamond heat spreader are preferably the same as or close to the size of the die or dies that the diamond heat spreader covers in a multi-chip package. Ideally, the lateral dimensions of the diamond heat spreader are significantly larger than the size of the dies the diamond heat spreader covers, e.g. the same size as the substrate of the device package, yet for cost considerations the diamond heat spreader may only cover one or more dies in the package, not all. For example, in implementations in which the processor is a compute tile in an AI IC device or GPU, the lateral dimensions of the compute tile dies are typically close to 33 mm×26 mm, which is close to the reticle limit, e.g. for EUV lithography equipment by ASML. The reticle limit refers to the maximum size of the image that can be projected onto a wafer during photolithography. In such implementations, it is generally desirable for the size of the diamond heat spreader 201 to be close to this size. Ideally the diamond spreader would be large enough to cover everything in the device package, including the processor 203 and memory stack 214. Single-crystal diamond wafers of up to 100 mm in lateral dimension are commercially available from Diamond Foundry Inc. of South San Francisco, California.

According to some aspects of the present disclosure the diamond heat spreader 201 may include multiple diamond plates bonded to the processor and/or the memory in a mosaic type arrangement sufficient to cover an area of the processor and/or memory. The filler material may be of the same size as each diamond plate. The filler material may cover multiple diamond plates, e.g. the filler material may cover the full area of the processor or the full mosaic type arrangement. The gaps between the diamond plates may be filled with a thermally conductive material that is easily applied locally, e.g. a solder paste, silver sinter paste, copper sinter paste, electro(less) plated copper, (hot) liquid metal (e.g. eutectic alloys), etc. and subsequently processed to ensure high thermal conductivity (e.g. reflow, or heating).

Each diamond plate in this implementation may have dimensions suitable for use with a pick and place machine for example and without limitation each diamond plate in the mosaic may have an area less than 50 mm×50 mm. In some implementations, the diamond plates that make up the heat spreader may be placed in the mosaic type pattern to cover only selected portions of the processor and/or memory stack while leaving other areas without a diamond plate. This may save resources by only covering problematic areas. The spaces between the diamond plates may be filled with the filler material or the same materials used to fill the gaps between the diamond plates, e.g. solder paste, indium, etc.

The filler material 202 may be any material with a Coefficient of Thermal Expansion (CTE) that suitably matches the CTE of diamond and sufficiently thermally conductive to wick away the heat from the diamond heat spreader. For example and without limitation the CTE of diamond is 1.1 e⁻⁶ per unit Kelvin (K⁻¹) at room temperature and materials with a CTE less than 20 e⁻⁶K⁻¹ and a thermal conductivity (TC) at room temperature of greater than 10 W·m⁻¹·K⁻¹ would be suitable such as silicon (CTE 2.56 e⁻⁶K⁻¹, TC 139 W·m⁻¹·K⁻¹), silicon carbide (CTE 2.77 e⁻⁶K⁻¹ , TC 390 W·m⁻¹·K⁻¹) copper (CTE 17 e⁻⁶K⁻¹, TC 401 W·m⁻¹·K⁻¹), gold (CTE 14 e⁻⁶K⁻¹, TC 318 W·m⁻¹·K⁻¹), silver (CTE 18 e⁻⁶K⁻¹, TC 406 W·m⁻¹·K⁻¹), nickel (CTE 13 e⁻⁶K⁻¹, TC 106 W·m⁻¹·K⁻¹), titanium (CTE 8.6 e⁻⁶K⁻¹, TC 17 W·m⁻¹·K⁻¹), platinum (CTE 9 e⁻⁶K⁻¹, TC 72 W·m⁻¹·K⁻¹), or iron (CTE 11.8 e⁻⁶K⁻¹, TC 79.5 W·m⁻¹·K⁻¹). Other metals that may be suitable: aluminum (Al), tungsten (W), and molybdenum (Mo), metal alloys, e.g. nickel iron alloys like invar, or composite metals, e.g. W—Cu, and Mo—Cu. Other materials may also be suitable for example and without limitation a carbon derivative e.g., diamond, diamond-like carbon (DLC), graphite, graphene, nanotubes, carbon fibers, etc. The carbon derivative may be the filler material by itself, or the carbon derivative may be part of a composite with another material, e.g. a polymer, metal, or ceramic. One example of a carbon derivative is a diamond-Cu composite. Another example is a diamond-Ag composite. The carbon derivative may be aligned or oriented along a preferred axis. Similarly, the filler material may be a ceramic such as Aluminum nitride (AlN), Aluminum Oxide (Al₂O₃), Silicon Nitride (Si₃N₄), Beryllium oxide (BeO), Boron Nitride (BN, e.g. cubic BN), and similar. Ceramic-metal composites may be the filler material, e.g. Al—Si, Al—SiC, or Mg—SiC. Other filler materials may be boron arsenide (e.g. cubic), metals suspended in a polymer matrix, e.g. gallium alloys in a polymer matrix. The filler material may be a stack of two or more layers on top of the diamond heat spreader which would result in a stack of three or more layers. The filler material may be a stack of diamond and silicon (resulting in a sandwich of diamond/diamond/silicon), a stack of copper and silicon (resulting in a sandwich of diamond/copper/silicon), a stack of diamond and SiC (resulting in a sandwich of diamond/diamond/SiC), a stack of copper and SiC. The top layer (e.g. Si or SiC) would facilitate the integration into the final device package.

Where the filler material 202 may be largely a passive solid, the filler material may be an active cooling element with cooling channels and single-phase or two-phase cooling. For example, the filler material may be a microchannel or impingement cooler made out of silicon. After device package fabrication, the top surface of the filler material is opened to connect the channels inside the filler material to the cooling fluid inlet and outlet. Another example, the filler material may be a microchannel or impingement cooler made out of silicon carbide, copper, graphite, diamond, or aluminum.

Where the filler material may be largely a passive solid or an active cooling element with cooling channels, the filler material may be a boiling enhancement coating for immersion cooling. For example, the filler material may be made out of porous silicon. After device package fabrication, the top surface of the filler material is opened to the porous bulk structure of the silicon. Another example, the filler material may be a boiling enhancement coating made out of silicon carbide, copper, graphite, diamond, or aluminum.

Where the filler material may be largely a passive solid to fill a gap to keep the diamond thin, or an active element with cooling channels, or a boiling enhancement coating, the filler material might be really thin and mainly serves the role of accurate height matching. Since accurate height matching is made easier by polishing, lapping, or grinding the multiple chiplets simultaneously after assembly, it may be beneficial to just add a thin layer of filler material on top of a relatively thick diamond. The filler material is not as much added to keep the diamond thin, but more to make it easier to match the height accurately by a final planarization (accurate height matching) step. In this case the filler material can be really thin, e.g. 5 micrometers to 25 micrometers, and is preferably soft, e.g. silicon.

The filler material may be bonded to the diamond heat spreader via any suitable method for example and without limitation, Plasma-Assisted-Bonding (PAB or fusion bonding), Surface Activated Bonding (SAB or COMBOND), Atomic Diffusion Bonding (ADB), thermocompression bonding (TCB), sintering (e.g. Cu or Ag), deposition (e.g. CVD, sputtering, e-beam evaporation), soldering, plating, electroless plating, etc. For example, copper foil may be bonded by TCB to a diamond heat spreader with suitable metallization on both surfaces (e.g. Cu, Au, Al, or Ag). Another example, SiC may be bonded to a diamond heat spreader by TCB (with suitable metallization on both surfaces, e.g. Cu, Au, Al, or Ag), PAB (with suitable dielectric coatings on both surfaces, e.g. silicon oxide or SiCN), or SAB. The filler material might be deposited onto the diamond heat spreader, or the diamond heat spreader might be deposited onto the filler material. For example, copper may be plated onto (metallized) diamond. Yet another example, (polycrystalline) silicon may be deposited by CVD onto diamond. Yet another example, (polycrystalline) SiC may be deposited by CVD or PVT (physical vapor transport) onto diamond. Yet another example, (polycrystalline) diamond may be deposited by CVD onto SiC. Yet another example, (polycrystalline) diamond may be deposited by CVD onto silicon. In yet another example, diamond may be deposited by CVD onto diamond, e.g. lower cost (e.g. higher growth rate), lower thermal conductivity diamond filler material may be deposited onto a higher cost (e.g. lower growth rate), higher thermal conductivity diamond heat spreader. It should be noted that various adhesion layers, barrier layers, nucleation layers, buffer layers, may be deposited on top of the diamond prior to deposition of the filler material, or on top of the filler material prior to deposition of the diamond. Adhesive layers may be used on the diamond surface (e.g. titanium or chromium) and the filler material surface (e.g. titanium, tantalum, or chromium). Barrier layers may be used on the diamond surface (e.g. nickel or Pt) or filler material surface (e.g. nickel, TiN, TaN, Pt). The top layer on the diamond surface may be Ag, Cu, Au, or part of the bondline material, e.g. Sn, or In. The top layer on the filler material surface may be Ag, Cu, Au, or part of the bondline material, e.g. Sn, or In.

The diamond surface is preferably not extensively lapped, grinded, or polished, since surface finishing diamond is costly. As such, as-grown diamond surfaces, as-sliced diamond surfaces, or diamond surfaces with minimal surface finishing are preferred. These diamond surfaces are rough surfaces with roughness values (Sa, or Ra) ranging from 0.5 nanometers up to 10 micrometers. Permanent bonding techniques suitable for rough surfaces require compliant bond materials during permanent bonding that result in thin, thermally conductive bond lines. Compliant bond materials that can be used for permanent bonding rough surfaces are sinter pastes (e.g. Ag or Cu paste), metals or metal alloys that are either malleable or liquid during bonding, whether elemental (e.g. indium), non-eutectic solder (e.g. lead-based Sn36Pb37, or lead-free SAC compositions), eutectic solder based on Sn, In, or Sb (e.g. specific compositions of Ag—In, Au—In, Au—Sn, Cu—Sn), transient liquid phase bond materials (TLPB, e.g. specific compositions based on Ag—In, Au—In, Ag—Sn, Au—Sn, Cu—Sn, or Ni—Sn), or adhesive polymers filled with liquid metals. The bond surfaces may be metallized prior to bonding the rough surfaces. Adhesive layers may be used on the diamond surface (e.g. titanium or chromium) and the filler material surface (e.g. titanium, tantalum, or chromium). Barrier layers may be used on the diamond surface (e.g. nickel or Pt) or filler material surface (e.g. nickel, TiN, TaN, Pt). The top layer on the diamond surface may be Ag, Cu, Au, or part of the bondline material, e.g. Sn, In, or a (non)-eutectic solder. The top layer on the filler material surface may be Ag, Cu, Au, or part of the bondline material, e.g. Sn, In, or a (non)-eutectic solder.

Several bonding techniques, however, have strict flatness and smoothness requirements. Both PAB (fusion bonding), and SAB (COMBOND) have surface roughness requirements of Sa<1 nm, preferably Sa<0.5 nm. Similarly, in order to reduce the necessary temperature and force for TCB, bond surface smoothness and flatness need to be controlled for TCB as well. As such, there is a need to smoothen the SCD surface not by removing SCD material by lapping, grinding, or polishing SCD, but by adding material to the rough SCD surface with this material more easily smoothened than SCD, and with a reasonable CTE and thermal conductivity, a smoothening material. Examples of smoothening materials that can be added on top of SCD that are more easily smoothened than SCD are silicon (e.g. CVD polycrystalline Si), SiC (e.g. CVD SiC or VPT SiC), or copper. Copper may be deposited by electroless plating. For electroless plating process conditions, see e.g. a recent 2015 review (in Microelectronics Engineering, 2015, entitled “30 years of electroless plating for semiconductor and polymer micro-systems”), and a 2016 review (in Journal of the Microelectronics and Packaging Society, 2015, entitled “Recent Progress in Electroless Plating of Copper”) The contents of which are incorporated herein by reference. Copper may be deposited by wet deposition, e.g. printing, jetting, or slot die coating, e.g. printing of copper nanopowders followed by thermal processing, e.g. by PulseForge of Austin Texas. Copper may be deposited by a copper sinter paste followed by sintering. Other smoothening material examples are graphite (e.g. CVD graphite), diamond-like carbon (CVD DLC), glass (e.g. spin-on-glass, or sol-gel), zinc, aluminum, brass, silver, or gold. After deposition of these smoothening materials, these materials on top of the rough diamond are subsequently surface finished (e.g. lapping, grinding, polishing, etching, or CMP) to the necessary flatness and smoothness. Adhesive layers may be used on the rough diamond surface (e.g. titanium or chromium). Barrier layers may be used on the rough diamond surface (e.g. nickel or Pt). Anneal steps to reduce voids in the smoothening material may be used. Anneal steps to increase the thermal conductivity of the smoothening material may be used.

Thus, the following examples of combining thinner diamond, rougher diamond, or thinner and rougher diamond with filler material may be used. For example, as shown in FIG. 2B the diamond heat spreader 201 may have a rough surface 221 at the interface with the processor IC device 203 that is smoothened by a smoothening material 220 and a smooth surface at the interface with the filler material 202. In another example as shown in FIG. 2C the diamond heat spreader 201 has a rough surface 222 that is smoothened by a smoothing material 223 at the interface with the filler material. In yet one more example as shown in FIG. 2D the diamond heat spreader 201 has a first side with a rough surface 221 that is smoothened by a first smoothening material 220 and a second side with a rough surface 222 that is smoothened by a second smoothing material 223. As discussed in the examples below, the smoothening material may be applied by any suitable known application method. One example uses a SCD with a rough surface smoothened by the smoothening material CVD polycrystalline silicon coated with a dielectric film (e.g. silicon oxide) bonded by PAB to the dielectric film (e.g. silicon oxide) of the IC device. The opposite side of the SCD is rough and smoothened by CVD polycrystalline silicon and similarly bonded by PAB (and dielectric films) to the filler material SiC. Another example uses an SCD with a rough surface smoothened by the smoothening material copper and bonded by TCB to the metallized (Cu) IC device. The opposite side of the SCD is rough and smoothened by copper and bonded by TCB to the filler material copper (foil). Yet another example uses a SCD with a rough surface smoothened by the smoothening material silicon and bonded by SAB to the IC device. The opposite side of the SCD is rough and smoothened by the smoothening material silicon and bonded by SAB to the filler material SiC. In yet another example, a SCD with a smooth surface is bonded by SAB to the IC device. The opposite side of the SCD is rough and smoothened by the smoothening material silicon and bonded by SAB to the filler material SiC. In yet another example, an SCD with a smooth surface is bonded by PAB (and dielectric films) to the IC device. The opposite side of the SCD is smooth and bonded by SAB to the filler material SiC. In yet another example, a SCD with a rough surface smoothened by the smoothening material silicon is bonded by SAB to the IC device. The opposite side of the SCD is rough yet the SCD is thick enough and does not require a filler material. In yet another example, a SCD with a smooth surface is bonded by SAB to the IC device without a filler material.

In simple 2D flip chip packages (e.g. FCBGA) as shown in FIG. 2E there is no need for height matching, since there is only die 253 (chiplet, or IC device). However, 2D packages may benefit from diamond heat spreaders 251, whether bonded and smoothened by diamond surface finishing, or bonded and smoothened by adding a smoothening material 270 to one or more rough diamond surface(s) 271.

Height matching may be necessary in chip packages with more than one chiplet (die, or IC device) horizontally interconnected. The previous paragraphs largely describe a 2.5D chip package based on an interposer. A common package with an interposer (silicon or organic) is the Chip-On-Wafer-On-Substrate (CoWoS) package. In this package there is one or more central compute dies surrounded by one or more high-bandwidth-memory (HBM) stacks where these compute dies and HBM stacks are horizontally interconnected via the interposer. These 2.5D chip packages are commonly used for AI chips or GPUs. It should be understood that height matching may be beneficial in other packages with two or more dies (chiplets, or IC devices) horizontally interconnected as well, whether by the substrate, a hybrid substrate, redistribution layers (RDL), interposer, or interconnect bridges. Examples of other packages that can benefit from integrating a diamond heat spreader with a filler material are as follows: Multi-Chip-Module (MCM) packages (no interposer). Advanced packages based on interconnect bridges, e.g. embedded multi-die interconnect bridges (EMIB). Multi-die packages based on fan-out wafer-level packaging (FOWLP) may benefit from height matching a diamond heat spreader with filler material as well. Similarly, 3D packages with horizontally interconnected chiplets may benefit from height matching a diamond heat spreader with filler material. Substrates may be typical laminates or made out of glass.

It should be understood that the use of smoothening materials or filler materials may benefit packages with both signal IC and power IC on the same side of the chiplet (or die) yet may also benefit packages with a backside power delivery network (BS-PDN). Dies with a BS-PDN are designed with the signal IC stack on the opposite side of the silicon and transistors than the power IC stack. Furthermore, 3D packages may benefit from either smoothening materials, filler materials, or both. 3D packages may be designed with various functions monolithically integrated into one die, or various functions physically separated over multiple dies, e.g. Dynamic RAM (DRAM), Static RAM (SRAM), computation, etc. Similarly, similar functions might exist on physically different dies (chiplets), either horizontally interconnected, or vertically interconnected, or both. Finally, it should be understood that besides silicon, other semiconductors may be used in these 2D, 2.5D, or 3D packages, e.g. compound semiconductors like GaAs, GaN, InP, SiC, etc.

Similarly, it should be understood that the use of smoothening materials or filler materials may benefit packages cooled by various cooling techniques, e.g. air cooling, 3D vapor chamber cooling, cold plate cooling, single phase cooling, two phase cooling, immersion cooling, microchannel cooling, impingement cooling, jet or spray cooling. The dimensions of the combination of diamond heat spreader 201 bonded to the filler material 202 may be chosen such that height from the common plane created by the interposer 205 of the processor 203 plus the diamond heat spreader 201 and filler material 202 is approximately the same as the height from the interposer 205 of the memory stack 204. In other words, the top side surface of the filler material 202 may substantially share a plane 207 with a top surface of the memory stack 214. There may be some height difference between the two stacks or from the plane 207 but preferably no more than 50 micrometers, even more preferred no more than 10 micrometers, even more preferred no more than 5 micrometers, yet even more preferred no more than 3 micrometers.

In some implementations the diamond heat spreader 201 and the filler material 202 may be manufactured separately and later attached to the processor 203 IC device. The dimensions of the diamond heat spreader and filler material may be chosen to achieve the desired height match with the height of the second IC device, e.g., the memory stack 214. For example, and without limitation, if the memory stack has a height from the interposer of 800 micrometers and the processor 203 has height from the interposer of 25 micrometers the combination diamond heat spreader and filler material would be made to around 800−25=775 micrometers. Due to the cost of manufacturing diamond heat spreaders, a heat spreader height of, for example and without limitation, less than 300 micrometers may be desirable and in such a case the filler material would make up the remaining 475 micrometers of height. After attachment of the diamond heat spreader and filler material combination, the filler material may be polished to ensure a height match with the nearby structures (e.g., stack of RAM devices).

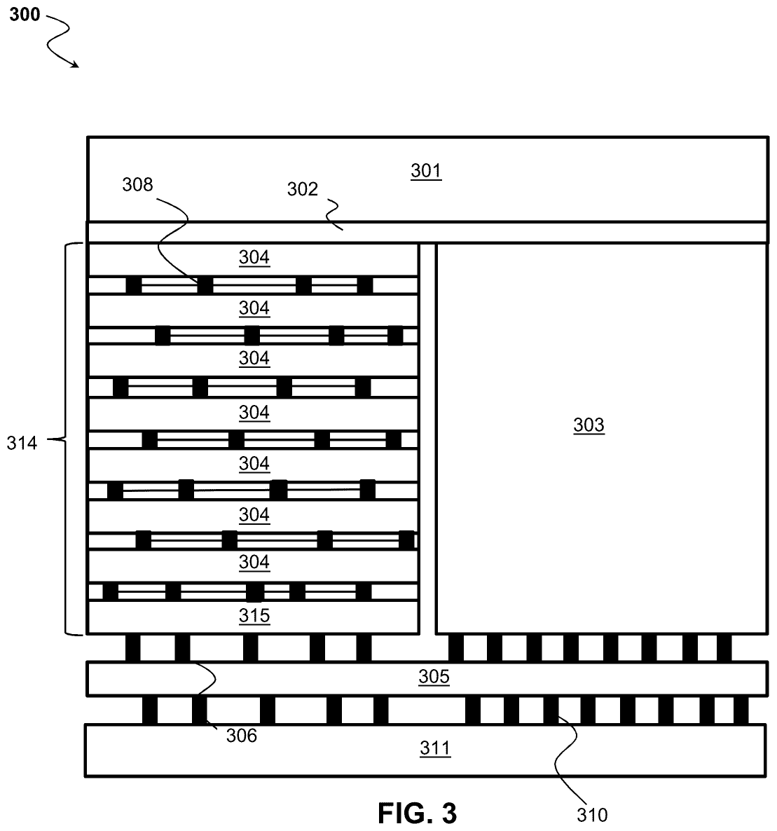

FIG. 3 depicts a side cross-sectional view of a device package having a diamond lid heat spreader according to an aspect of the present disclosure. In this implementation the device package 300 includes a diamond lid 301 which also acts as a heat spreader. The diamond lid 301 may be made from polycrystalline diamond or more preferably single crystal diamond. The diamond heat spreader 301 here covers both the processor 303 IC Device and a memory stack 314 having a stack of memory IC devices 304. Note here that the processor 303 includes a thick inactive substrate and may be polished down to match the height of the memory stack 314. A thermal interface material 302 may be deposited over the processor 303 and memory stack 314 to fill gaps and ensure a good thermal connection between the IC devices and diamond lid 301. Both the IC devices and the diamond lid may be metallized to improve adhesion to the thermal interface material 302, e.g. indium TIM. As with the previous implementations the memory stack 314 includes one or more memory devices 304 disposed on top of each other and communicatively connected to one another by one or more memory interconnects 308. Similarly, the processor 303 and the memory stack 314 are communicatively connected (horizontally) to one another by a device interconnect 305 (e.g. interposer) and through vertical conductive interconnects 306. The interposer 305 may be bonded and/or communicatively connected to a ceramic or laminate substrate 311 by large vertical interconnects 310 for example and without limitation, large solder balls. The top surface of the interconnect 305 under the vertical interconnects 306 defines a plane on which the processor and stack of memory devices sit and from which the height of each IC device or stack of IC devices may be determined.

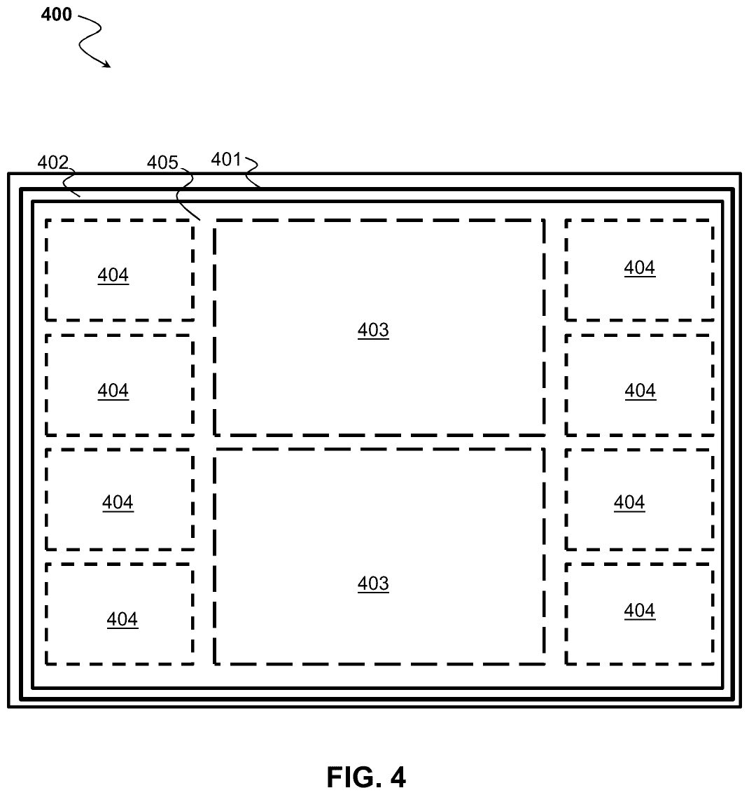

FIG. 4 is a top-down schematic view of a device package 400 with a diamond lid heat spreader according to an aspect of the present disclosure. As shown here the diamond lid heat spreader 401 extends the length and width of the package covering a stack of memory devices 404 and processor 403. The diamond lid heat spreader 401 may be attached to the device package by a rigid sidewall 402. The rigid sidewall 402 may be any suitable device package sidewall material for example and without limitation adhesive (with or without particle fillers), composites, glass frit, molding compound, graphite, or a metal such as copper, aluminum, invar, or steel. The sidewall may be attached by any suitable attachment means for example and without limitation, soldering, gluing, sintering, compression fitting, clipping, etc. Thermal interface material or other material may fill the spaces 405 between the processors 403 and stacks of memory devices 404 as well as any mismatch in height between the top of the processors, top of the memory device stacks and the bottom of the diamond lid heat spreader 401.

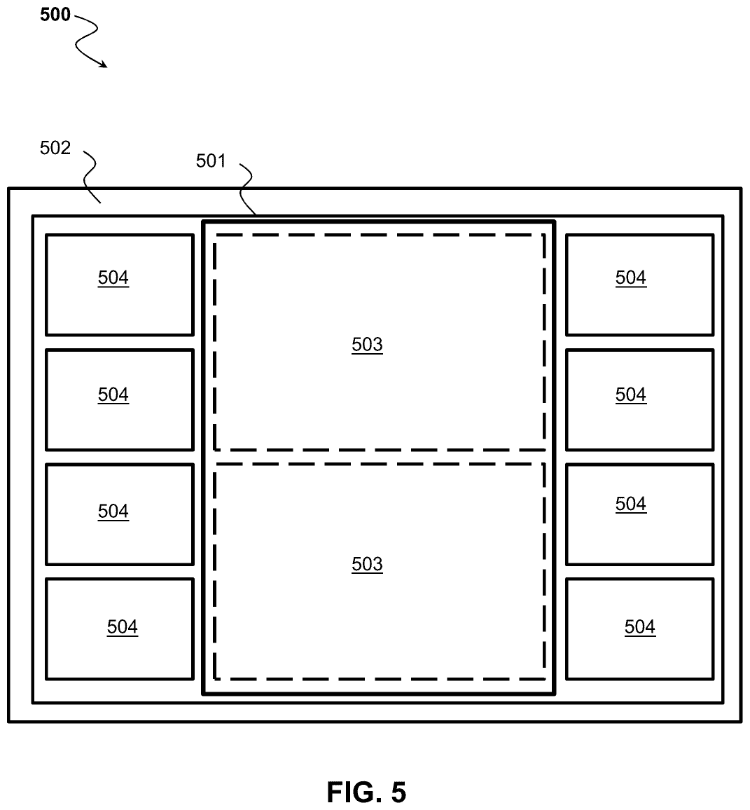

FIG. 5 is a top-down schematic view of a device package 500 having a processor coupled to a single diamond heat spreader bonded to filler material height matched to a second IC device according to an aspect of the present disclosure. In this implementation, the diamond heat spreader and filler material combination 501 covers both processors 503 in the device package 500. The diamond heat spreader and filler material combination 501 is chosen such that the side of the combination opposite the side attached to the processors shares a plane with the exposed side of the stack of memory devices 504. This ensures that good thermal connection is made with additional heat mitigation devices (not shown), e.g. a copper lid, a cold plate, a 3D vapor chamber, a microchannel cooler, or an impingement cooler.

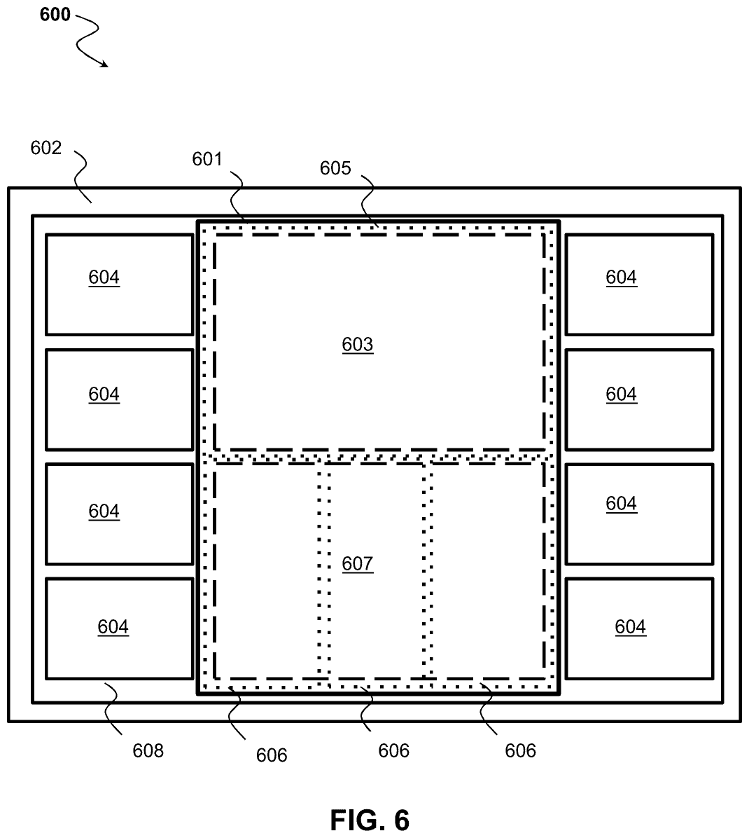

FIG. 6 depicts a top-down schematic view of the device package having a processor coupled to multiple diamond heat spreaders bonded to filler material height matched to a second IC device according to an aspect of the present disclosure. In this implementation are multiple diamond heat spreaders attached to the filler material 601. The first diamond heat spreader 605 is attached to a first processor 603 IC device and a second diamond heat spreader 606 is attached to a second processor 607 IC device. While this implementation is less efficient at spreading the heat generated by the IC devices, overall, it may still be suitably effective eliminating hot spots on each IC device and thus may reduce failures due to overheating. Similar to above dimensions of the diamond heat spreaders 605, 606 and filler material 601 combination is chosen such that the side of the combination opposite the side attached to the processors shares a plane with the exposed side of the stack of memory devices 604. That is, the top of the filler material 601 is approximately the same height from the top of the interposer 608 as the top of the stack of memory 604. The interposer 608 is on top of the substrate 602. The variance of height between the filler material and the top of the stack of memory devices may be less than 10 micrometers, preferably less than 5 micrometers, even more preferred less than 3 micrometers. While the above-described implementation depicts two diamond heat spreaders over each of the IC devices, aspects of the present disclosure are not so limited and there may be any number of diamond heat spreaders bonded to each of the IC devices in any pattern for example and without limitation a mosaic type pattern with a minimal space between each diamond heat spreader. By way of example, and not by way of limitation, the second diamond heat spreader 606 is shown as being made up of three separate diamond plates.

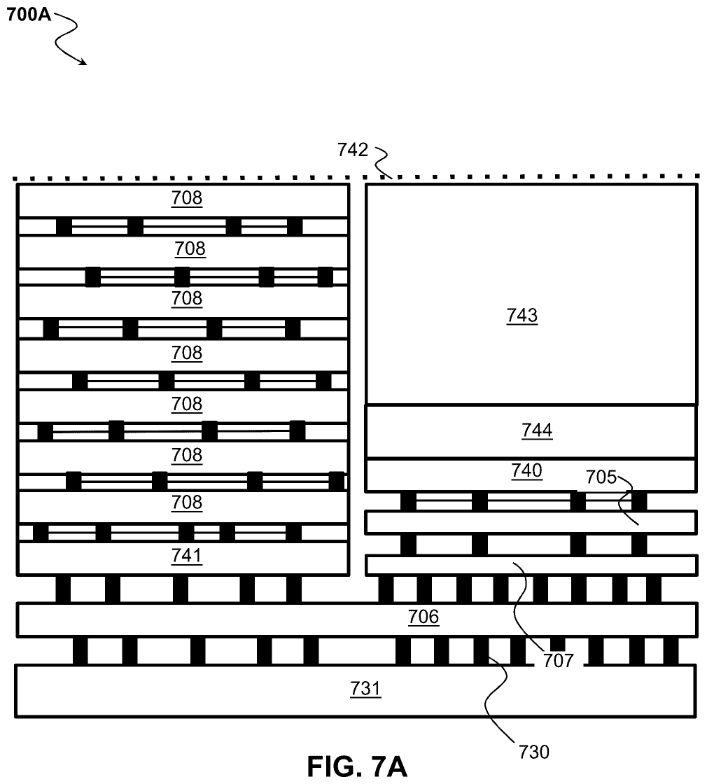

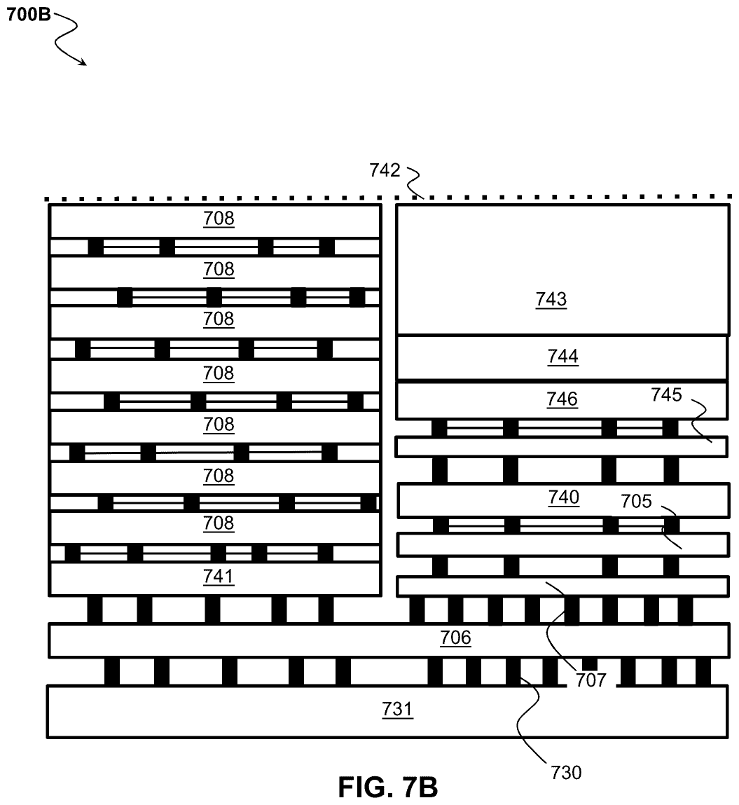

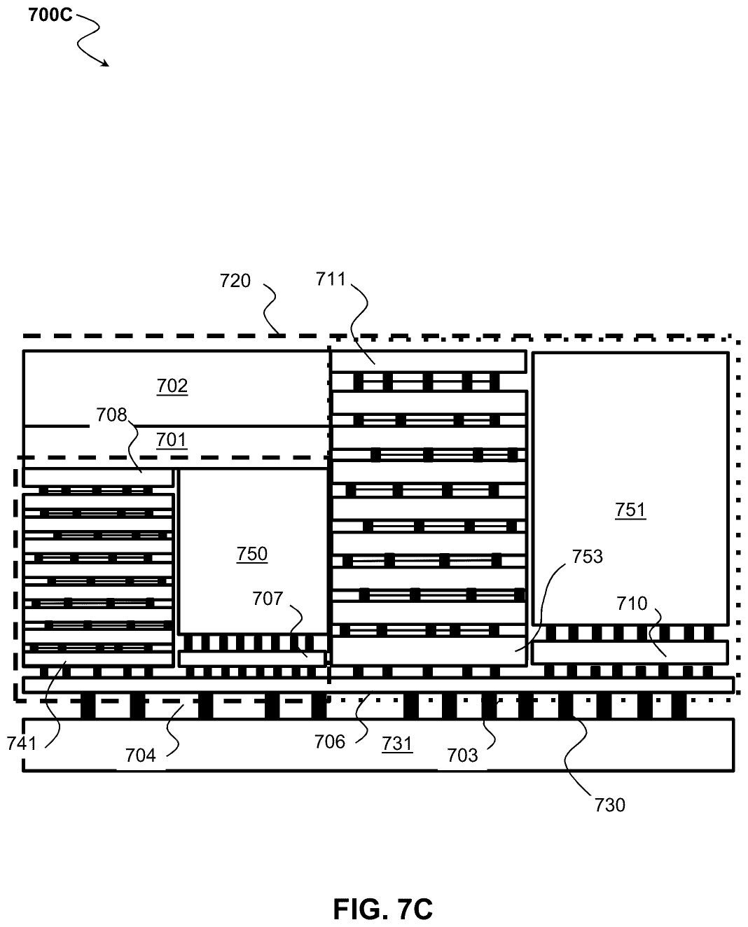

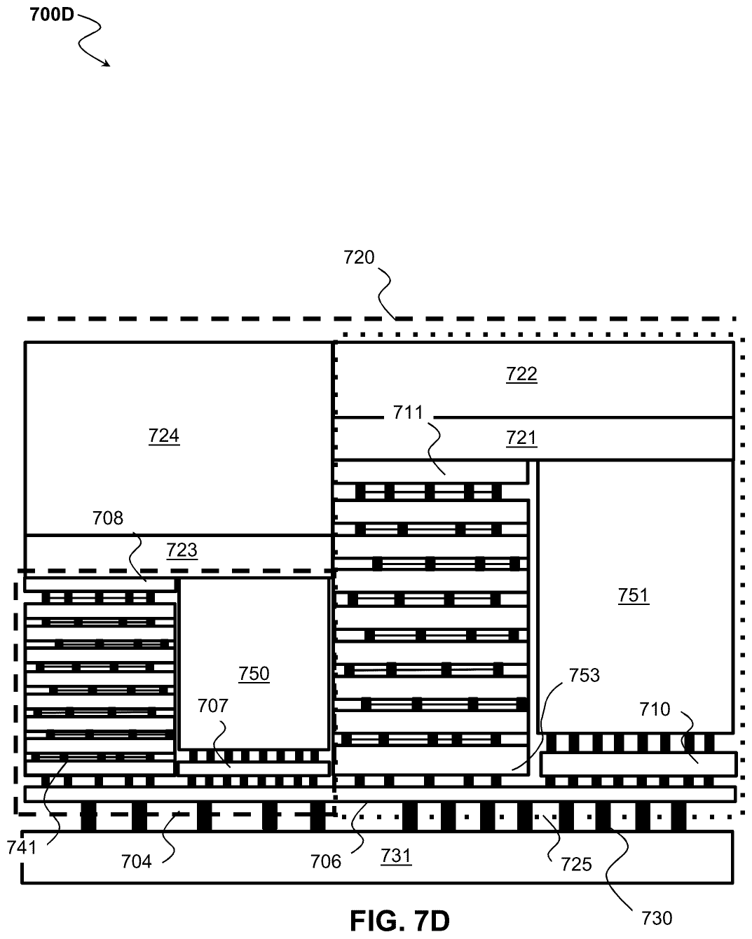

FIG. 7A depicts a cross-section view of a device package 700A having a 3-D stacked processing system IC device with a diamond heat spreader with height matching to a memory stack according to an aspect of the present disclosure. In this implementation a first processing unit 705 is stacked with one or more memory device(s) 740 over the first processing unit relative to an interposer 706 and a ceramic or laminate substrate 731. The interposer 706 may be bonded and/or communicatively coupled to the ceramic or laminate substrate 731 by vertical interconnects 730 such as, without limitation, solder balls, pillars, or bumps. In some alternative implementations the one or more memory devices may be stacked below the processing unit. The memory devices may be any suitable memory device for example and without limitation, SRAM or DRAM. A backside power interconnect 707 may deliver power to the processing unit 705 and memory device 740 stack. A first stack of memory devices 708 is located next to the processing unit 705 and memory device 740 stack. The first stack of memory devices 708 may include one or more memory logic 741 IC devices in the stack. An interconnect 706 may provide a communicative connection between the processing unit 705 and memory device 740 stack and the first stack of memory devices 708 and memory logic 741 IC device. Additionally, the interconnect may physically locate the processing unit 705 and memory device 740 stack next to the first stack of memory devices 708 and memory logic 741 IC device. As shown, there is a significant height difference between the top first stack of memory devices 708 and the top of the memory device 740. A diamond heat spreader 744 may be bonded to a side of the memory device 740 and a filler material 743 may be bonded to the diamond heat spreader. The diamond heat spreader 744 and filler material 743 may have sufficient dimensions that a top surface of the filler material 744 matches 742 a top surface of the memory device stack 708 when attached to the memory device 740. In some alternative implementations the backside power delivery may be omitted or below the one or more memory devices with the processing unit on top of the one or more memory devices and in which case the diamond heat spreader may be bonded to the processing unit. Additionally, as discussed above, one or more surfaces of the diamond substrate that are to participate in bonding may be rough surfaces and may be smoothened with a smoothening material or bonded via a compliant material which is omitted from these drawings for clarity.

FIG. 7B depicts a cross-section view of a device package 700B having a 3-D stacked processing system IC device with multiple stacked processing units and a diamond heat spreader with height matching to a memory stack according to an aspect of the present disclosure. This implementation is similar to the implementations shown in FIG. 7A but includes a first processing unit 705 paired with one or more first memory devices 740 and stacked on top of 740 a second processing unit 745 paired with one or more second memory devices 746. The first processing unit 705 and one or more first memory devices 740 may be communicatively connected to the second processing unit 745 and one or more second memory devices 746 by vertical interconnects. As with the previous implementation the diamond heat spreader 744 and filler material 743 may be bonded to the memory device 746 and dimensioned to match the height 742 of the top of the memory device 708 stack. A backside power interconnect 707 may be present below the processing unit 705. A backside power interconnect may be present below the processing unit 745. In yet another implementation the backside power delivery may be omitted for one or more of the processing units or memory devices.

FIG. 7C depicts a cross-section view of a device package 700C having 3-dimensional (3D) stacked processing system IC devices and a diamond heat spreader with height matching according to an aspect of the present disclosure. In the implementation shown a first IC device 704 and a second IC device 703 are each in a 3-dimensional stacked configuration with backside power delivery. The depicted first IC device 704 is a complete processing system having a processing stack 750 and a stack of memory devices 708. The stack of memory devices 708 may also include a memory logic IC device 741. Similarly, the second IC device 703 is a complete processing system having processing stack 751 and stack of memory devices 711. Here, the processing stack 750 and processing stack 751 may include one or more processing units and, in some implementations, may include one or more memory devices paired with at least one of the one or more processors arranged in a vertical stacked configuration. Additionally, the stack of memory device 711 may include a memory device logic chip 753. The first IC device 704 has a 3-dimensional architecture with backside power delivery. The device stack includes a backside interconnect 707 and an interposer 706. Similarly, the second IC device 703 has a 3-dimensional architecture with backside power delivery with a backside interconnect 710 and an interposer 706. As shown the first IC device 704 and the second IC device 703 are communicatively coupled through the interposer 706. Here the top of the interposer 706 where the conductive vertical interconnects attach to the IC device stack may prescribe a common plane from which the height of the first IC device 704 and the height of the second IC device 703 may be measured. As shown the first IC device 704 has a lower height from the common plane of the interposer 706 than the second IC device 703. In other words, the top of the first IC device 704, here the top of the processing stack 750, does not share the plane 720 described by a top of the second IC device 703, the top of the processing stack 751.

This height difference can cause difficulties in attachment and effectiveness of cooling systems for the stack processors systems, as such the diamond heat spreader 701 bonded to filler material 702 may be attached to the processing stack 750 of the first IC device 704. The dimensions of the diamond heat spreader 701 and filler material 702 are chosen to match the height of the second IC device 703 from the common plane of the interposer 706 when attached to the first IC device 704. The filler material 702 may also be polished, lapped, or grinded after attachment to create an even more accurate height match 720. While in the implementation shown the first IC device 704 and Second IC device 703 are processor systems, aspects of the present disclosure are not so limited and the IC devices may be an integrated circuit device and/or 3D architecture integrated circuit device such as a GPU, graphics processing system, processor, processor system, micro-controller, power controller, transistor, etc. Additionally, while the 3D architecture shown includes backside power delivery architectures, aspects of the present disclosure are not so limited and may include any type of stacking architecture. In one implementation, the processing unit stack 750 may contain more than one backside power delivery unit. In another implementation, the processing unit 751 may include more than one backside power delivery unit. In yet another implementation, both processing unit stack 750 and 751 may contain more than one backside power delivery unit. In yet another implementation, both processing unit stack 750 and 751 may contain no backside power delivery units.

FIG. 7D depicts a cross-section view of a device package 700D having 3-dimensional stacked processing system IC devices and two diamond heat spreaders with height matching according to an aspect of the present disclosure. In this implementation both the first IC device 704 and the second IC device 725 are attached to separate diamond heat spreaders 723, 721, respectively, that are, in turn, bonded to respective filler materials 724, 722. For the sake of simplicity of explanation, the diamond heat spreader 721 and filler material 722 may be considered part of the second IC device 725, which, as discussed above, may include processing unit stack 751 and stack of memory devices 711 connected via interposer 706 and backside interconnect 710. The first IC device 704 is attached to the diamond heat spreader 723 bonded to filler material 724. Here a dimension of the diamond heat spreader 723 and the filler material 724 is chosen to match the height 720 from the shared plane created by the top of the interposer 706 with the top of the filler material 722 of the second IC device 725 when attached to the first IC device 704. In some implementations the first IC device filler material 724 and second IC device filler material 722 may be planarized and/or polished to create a level and smooth surface for later attachment to other heat spreaders or cooling apparatus such as heat sinks. In some alternative implementations the filler material may be continuous between diamond heat spreader 721 and diamond heat spreader 723. In such cases the filler material may be machined to the proper dimensions prior to attachment of the heat sinks.

While the present disclosure shows height matching to a second IC device, aspects of the present disclosure are not so limited, and the combination of diamond heat spreader and filler material may be height matched to one or more other IC devices when attached to a first IC device. Likewise, while the disclosure discusses height matching to other IC devices, aspects are not so limited and the diamond heat spreader bonded to the filler material may be height matched with any feature such as passives (capacitors, diodes, inductors), voltage regulators, photonics, antennas, sensors, power amplifiers, wireless communication components, wired communication components, optical communication components, etc. Thus, the above-described device package may provide enhanced heat spreading compared to traditional silicon substrate in new 2.5-dimensional (2.5D) and 3-dimensional (3D) device packages without a significant amount of manufacturing changes. The heat spreader and filler material can be attached to thinned IC devices and provide a height matched surface for affixing additional spreading or cooling apparatus or finishing for the device package.

It is noted that in any of the above-described examples, where a diamond heat spreader is shown or described as being a single plate or wafer, in alternative implementations, the heat spreader may include multiple diamond (e.g., SCD) plates, which may be bonded to one or more IC devices in a mosaic type arrangement sufficient to cover an area of the one or more IC devices.

While the above is a complete description of the preferred embodiment of the present invention, it is possible to use various alternatives, modifications, and equivalents. Therefore, the scope of the present invention should be determined not with reference to the above description but should, instead, be determined with reference to the appended claims, along with their full scope of equivalents. Any feature described herein, whether preferred or not, may be combined with any other feature described herein, whether preferred or not. In the claims that follow, the indefinite article “A.” or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A device package including:
a diamond heat spreader;
a filler material bonded to a first side of the diamond heat spreader;
a first integrated circuit (IC) device coupled to a second side of the diamond heat spreader opposite the filler material;
a second IC device, wherein a first side of the filler material opposite of a side bonded to the diamond heat spreader shares a horizontal plane with a top side of the second IC device.

2. The device package of claim 1 wherein the diamond heat spreader includes one or more single crystal diamond plates.

3. The device package of claim 1, wherein the diamond heat spreader includes two or more diamond plates.

4. The device package of claim 3, wherein the two or more diamond plates are arranged in a mosaic pattern with respect to the first IC device.

5. The device package of claim 4, wherein the two or more diamond plates are arranged in a mosaic sufficient to cover an area of the first IC device.

6. The device package of claim 1 wherein the device package includes interconnects between the first IC device and the second IC device horizontally.

7. The device package of claim 6 wherein the device package includes interconnects between the first IC device and the second IC device horizontally with one or more of the interconnect technologies selected from a list consisting of: interposer, interconnect bridge, redistribution layers, and substrate.

8. The device package of claim 1 wherein the first IC device includes a processor.

9. The device package of claim 1 wherein the second IC device includes a Random Access Memory (RAM).

10. The device package of claim 1 wherein the first IC device is a first processing unit stack, wherein the processing unit stack includes one or more processor dies and one or more RAM dies in a vertical stack.

11. The device package of claim 1 wherein the second IC device is a second processing unit stack, wherein the processing unit stack includes one or more processor dies and one or more RAM dies in a vertical stack.

12. The device package of claim 1 wherein the first IC device is coupled to an interconnect on a side opposite the side coupled to the diamond heat spreader.

13. The device package of claim 12 wherein the second IC device is coupled to the interconnect.

14. The device package of claim 1 wherein the first IC device includes a graphics processing unit (GPU).

15. The device package of claim 1 wherein a height difference in the plane between the surface of the second IC device and filler material is less than 25 micrometers.

16. The device package of claim 1 wherein the filler material includes silicon carbide.

17. The device package of claim 1 wherein the filler material includes, one or more materials selected from a list consisting of silicon, diamond, silicon carbide, boron nitride, boron arsenide, aluminum nitride, silicon nitride, beryllium oxide, copper, aluminum, gold, silver, nickel, and iron.

18. The device package of claim 1 wherein the filler material includes a metal, metal alloy, ceramic, polymer-metal composite, or metal-ceramic composite.

19. The device package of claim 1 wherein the filler material includes one or more of graphite, graphene, and carbon nanotubes.

20. The device package of claim 1 wherein the diamond heat spreader is less than 500 micrometers thick.

21. The device package of claim 1 wherein the filler material is greater than 250 micrometers thick.

22. The device package of claim 1 wherein the diamond heat spreader has a horizontal length of greater than 10 millimeters.

23. The device package of claim 1 wherein the diamond heat spreader has a horizontal width of greater than 10 millimeters.

24. The device package of claim 1 wherein the diamond heat spreader comprises two or more single crystal diamond plates.

25. The device package of claim 1 wherein the filler material includes cooling channels.

26. The device package of claim 1 wherein the filler material is configured to function as a boiling enhancement coating.

27. A composition of matter comprising:
a diamond heat spreader bonded to a filler material wherein dimensions of the filler material are chosen such that when the diamond heat spreader is bonded to the top of a first IC device the combined height of the first IC device, diamond heat spreader and filler material from a common plane is approximately the same as the height of a second IC device from the common plane.

28. The composition of matter of claim 27 wherein the diamond heat spreader includes one or more single crystal diamond plates.

29. The composition of matter of claim 27, wherein the diamond heat spreader includes two or more diamond plates.

30. The composition of matter of claim 29, wherein the two or more diamond plates are arranged in a mosaic pattern with respect to the first IC device.

31. The composition of matter of claim 30, wherein the two or more diamond plates are arranged in a mosaic sufficient to cover an area of the first IC device.

32. The composition of matter of claim 27 wherein the first IC device includes a processor.

33. The composition of matter of claim 27 wherein the second IC device includes a Random Access Memory (RAM).

34. The composition of matter of claim 27 wherein the first IC device is a first processing unit stack, wherein the processing unit stack includes one or more processor dies and one or more RAM dies in a vertical stack.

35. The composition of matter of claim 27 wherein the second IC device is a second processing unit stack, wherein the processing unit stack includes one or more processor dies and one or more RAM dies in a vertical stack.

36. The composition of matter of claim 27 wherein the first IC device includes a graphics processing unit (GPU).

37. The composition of matter of claim 27 wherein a difference in height between the second IC device and the combined height of the filler material, diamond heat spreader and first IC device is less than 25 micrometers.

38. The composition of matter of claim 27 wherein the filler material includes silicon carbide.

39. The composition of matter of claim 27 wherein the filler material includes, one or more materials selected from a list consisting of silicon, diamond, silicon carbide, boron nitride, boron arsenide, aluminum nitride, silicon nitride, beryllium oxide, copper, aluminum, gold, silver, nickel, magnesium, and iron.

40. The composition of matter of claim 27 wherein the filler material includes a metal, metal alloy, ceramic, polymer-metal composite, or metal-ceramic composite.

41. The composition of matter of claim 27 wherein the filler material includes one or more of graphite, graphene, and carbon nanotubes.

42. The composition of matter of claim 27 wherein the diamond heat spreader is less than 500 micrometers thick.

43. The composition of matter of claim 27 wherein the filler material is greater than 250 micrometers thick.

44. The composition of matter of claim 27 wherein the diamond heat spreader has a horizontal length of greater than 10 millimeters.

45. The composition of matter of claim 27 wherein the diamond heat spreader has a horizontal width of greater than 10 millimeters.

46. The composition of matter of claim 27 wherein the diamond heat spreader comprises two or more single crystal diamond plates.

47. A device package including:
a diamond heat spreader; a smoothening material smoothing a rough diamond surface;
a filler material bonded to a first side of the diamond heat spreader;
a first integrated circuit (IC) device coupled to a second side of the diamond heat spreader opposite the filler material;
a second IC device wherein a first side of the filler material opposite of a side bonded to the diamond heat spreader shares a horizontal plane with a top side of the second IC device.

48. The device package of claim 47 wherein the diamond heat spreader includes single crystal diamond.

49. The device package of claim 47, wherein the diamond heat spreader includes two or more diamond plates.

50. The device package of claim 49, wherein the two or more diamond plates are arranged in a mosaic pattern with respect to the first IC device.

51. The device package of claim 50, wherein the two or more diamond plates are arranged in a mosaic sufficient to cover an area of the first IC device.

52. The device package of claim 47 wherein the smoothening material includes, one or more materials selected from a list consisting of silicon, silicon carbide, copper, gold, silver, or glass.

53. The device package of claim 47 wherein the filler material includes, one or more materials selected from a list consisting of silicon, diamond, silicon carbide, boron nitride, boron arsenide, aluminum nitride, silicon nitride, beryllium oxide, copper, aluminum, gold, silver, nickel, magnesium, and iron.

54. A device package including:
a diamond heat spreader; a smoothening material smoothing a rough diamond surface;
a first integrated circuit (IC) device coupled to a side of the diamond heat spreader.

55. The device package of claim 54 wherein the diamond heat spreader includes single crystal diamond.

56. The device package of claim 54, wherein the diamond heat spreader includes two or more diamond plates.

57. The device package of claim 56, wherein the two or more diamond plates are arranged in a mosaic pattern with respect to the first IC device.

58. The device package of claim 57, wherein the two or more diamond plates are arranged in a mosaic sufficient to cover an area of the first IC device.

59. The device package of claim 54 wherein the smoothening material includes, one or more materials selected from a list consisting of silicon, silicon carbide, copper, gold, silver, or glass.

60. A device package including:
a diamond heat spreader; a compliant bond material in contact with a diamond side;
a filler material bonded to a first side of the diamond heat spreader;
a first integrated circuit (IC) device coupled to a second side of the diamond heat spreader opposite the filler material;
a second IC device wherein a first side of the filler material opposite of a side bonded to the diamond heat spreader shares a horizontal plane with a top side of the second IC device.

61. The device package of claim 60 wherein the diamond heat spreader includes single crystal diamond.

62. The device package of claim 60, wherein the diamond heat spreader includes two or more diamond plates.

63. The device package of claim 62, wherein the two or more diamond plates are arranged in a mosaic pattern with respect to the first IC device.

64. The device package of claim 63, wherein the two or more diamond plates are arranged in a mosaic sufficient to cover an area of the first IC device.

65. The device package of claim 60 wherein the compliant bond material includes, one or more materials selected from a list consisting of indium, indium silver, indium gold, indium copper, tin, tin copper, tin silver, tin gold, or tin nickel.

66. A device package including:
a diamond heat spreader; a compliant bond material in contact with a diamond side;
a first integrated circuit (IC) device coupled to a side of the diamond heat spreader.

67. The device package of claim 66 wherein the diamond heat spreader includes single crystal diamond.

68. The device package of claim 66, wherein the diamond heat spreader includes two or more diamond plates.

69. The device package of claim 68, wherein the two or more diamond plates are arranged in a mosaic pattern with respect to the first IC device.

70. The device package of claim 69, wherein the two or more diamond plates are arranged in a mosaic sufficient to cover an area of the first IC device.

71. The device package of claim 66 wherein the compliant bond material includes, one or more materials selected from a list consisting of indium, indium silver, indium gold, indium copper, tin, tin copper, tin silver, tin gold, or tin nickel.
